(19) United States
(12) Patent Application Publication
(10) Pub. No.: US 2008/0252336 A1
(43) Pub. Date: Oct. 16, 2008

(54) Non-Contacting Interrogation of System States

(75) Inventor: Nils Krumme, Feldafing (DE)

Correspondence Address: DAFFER MCDANIEL LLP, P.O. BOX 684908, AUSTIN, TX, 78768, US

(73) Assignee: SCHLEIFRING UND APPARATEBAU GMBH, Fuerstenfeldbruck (DE)

(21) Appl. No.: 12/115,631

(22) Filed: May 6, 2008

Related U.S. Application Data
(63) Continuation of application No. PCT/EP2006/010633, filed on Nov. 7, 2006.

(30) Foreign Application Priority Data
Nov. 8, 2005 (DE) 102005053543.7

(51) Int. Cl. G01R 23/02

(52) U.S. Cl. 327/39

(57) ABSTRACT

A device for non-contacting interrogation, without auxiliary power, of system states of a part that is rotatable relative to a fixed part comprises a coil on the rotatable part and a coil on the fixed part. The coils are mutually coupled, one being fed by a signal generator generating different frequencies, whilst the other coil is supplemented with at least one capacitance to form a resonance circuit. Further impedances can be added by means of switch elements to change a resonance frequency and form an interrogation circuit. By determining a resonance frequency on a signal generator side it is possible to draw conclusions about an impedance on an opposite side and to assign this to a switch element which is closed.

### CROSS-REFERENCE TO RELATED APPLICATIONS

This application is a continuation of pending International Application No. PCT/EP2006/010633 filed Nov. 7, 2006, which designates the United States and claims priority from German Application No. 102005053543.7 filed Nov. 8, 2005 (now abandoned).

### BACKGROUND OF THE INVENTION

1. Field of the Invention

The invention relates to non-contacting rotary joints.

2. Description of the Prior Art

Rotary joints, often also known as slip rings, are used for transmitting electric signals between mutually rotatable parts. Various different rotary joints are known. Contacting slip rings, for example in which metal or carbon brushes run on mainly metallic slide tracks, are used for electrical transmission. Non-contacting rotary joints are based on the principle of inductive or capacitive coupling. These rotary joints are virtually free from wear and tear as compared with contacting slip rings because no mechanical contact is necessary between the two rotary parts. As a result of the physical separation of the two rotatable parts, such rotary joints can be encapsulated in an excellent way against environmental influences. The disadvantage of non-contacting rotary joints is the usually significantly higher cost as compared with that of mechanical slip rings.

DE 10084415 discloses a non-contacting rotary joint for the steering wheel of a motor vehicle. A clock signal modulated on a carrier is transmitted from the motor vehicle to the steering wheel by means of loop antennas in the motor vehicle and in the steering wheel. For the purpose of signaling switch states of the steering wheel, an attenuation of the loop antennas is effected via a pulse switch integrated in the steering wheel. This can be detected on the motor vehicle by a corresponding reduction of the signal amplitude. The supply of power to the electronic system in the steering wheel is made by means of a separate electrically conducting rotary joint. If such a power supply were also to be implemented in a non-conducting manner, additional components would be necessary.

It is the object of the invention to design a system for querying system states such as switch positions between a fixed and a rotating part, which system is further simplified in comparison with the state of the art, whilst an additional supply of power to the components of the rotating part can be dispensed with.

### BRIEF SUMMARY OF THE INVENTION

In accordance with the invention, this object is achieved by a device for non-contacting interrogation of system states of a part that is rotatable relative to a fixed part, comprising: a first coil on the fixed part; a signal generator for feeding the first coil; a second coil on the rotatable part, which is magnetically coupled with the first coil, wherein the second coil is supplemented with at least one capacitance to form a resonance circuit; at least one switch element for connecting or disconnecting at least one further impedance into or from the resonance circuit is provided, whereby the first coil, the second coil, the at least one capacitance, the at least one switch element, and also the at least one further impedance form an interrogation circuit; and an evaluation unit is provided on the fixed part for changing a frequency of the signal generator until at least one resonance frequency of the interrogation circuit is attained, and for drawing conclusions about a state of the at least one switch element from at least one of an attained resonance frequency and an attenuation of the interrogation circuit.

The above object is also achieved by a device for non-contacting interrogation of system states of a part that is rotatable relative to a fixed part, comprising: a first coil on the fixed part; a signal generator for feeding the first coil; a second coil on the rotatable part, which is magnetically coupled with the first coil, wherein the second coil is supplemented with at least one capacitance to form a resonance circuit; at least one switch element for connecting or disconnecting at least one further impedance into or from the resonance circuit is provided, whereby the first coil, the second coil, the at least one capacitance, the at least one switch element, and also the at least one further impedance form an interrogation circuit; and the signal generator is adapted to be freely oscillating based on the resonance circuit, and an evaluation unit is provided on the fixed part for evaluating a frequency of the signal generator and drawing conclusions about a state of the at least one switch element from at least one of a resonance frequency and an attenuation of the interrogation circuit.

The above object is also achieved by a device for non-contacting interrogation of system states of a part that is rotatable relative to a fixed part, comprising: a first coil on the fixed part; a signal generator for feeding the first coil; a second coil on the rotatable part, which is magnetically coupled with the first coil, wherein the second coil is supplemented with at least one capacitance to form a resonance circuit; at least one switch element for connecting or disconnecting at least one further impedance into or from the resonance circuit is provided, whereby the first coil, the second coil, the at least one capacitance, the at least one switch element, and also the at least one further impedance form an interrogation circuit; and an evaluation unit is provided on the fixed part for changing a frequency of the signal generator within a predetermined frequency range and simultaneously performing measurements of at least one electrical parameter selected from frequency, amplitude, and phase on the first coil, and based on this draws conclusions about a state of the at least one switch element.

The above object is also achieved by a device for non-contacting interrogation of system states of a part that is rotatable relative to a fixed part, comprising: a first coil on the fixed part; a signal generator for feeding the first coil; a second coil on the rotatable part, which is magnetically coupled with the first coil, wherein the second coil is supplemented with at least one capacitance to form a resonance circuit; at least one switch element for connecting and disconnecting at least one further impedance into or from the resonance circuit is provided, whereby the first coil, the second coil, the at least one capacitance, the at least one switch element, and also the at least one further impedance form an interrogation circuit; and an evaluation unit is provided on the fixed part for controlling the signal generator so that it emits a signal having a plurality of frequencies and simultaneously performs measurements of at least one electrical parameter selected from frequency, amplitude, and phase on the first coil, and based on this draws conclusions about a state of the at least one switch element.

In the above described devices means can be provided for a plausibility check by comparing determined electrical parameters with predetermined values in order to indicate faults of the arrangement in case of large deviations.

Furthermore, the at least one further impedance can be dimensioned so that distinct resonance frequencies occur for all states of the switch elements.

In addition, optionally at least one of the first coil and the second coil can comprises a plurality of coil sections.

In accordance with the invention, the above object is also achieved by a method for non contacting interrogation of system states of a part that is rotatable relative to a fixed part, with the fixed part having a first coil fed by a signal generator, and the rotatable part having a second coil which is magnetically coupled with the first coil, the method comprising the following steps: (i) supplementing the second coil with at least one capacitance to form a resonance circuit; (ii) adding at least one further impedance using at least one switch element, whereby the first coil, the second coil, the at least one capacitance, the at least one switch element, and also the at least one further impedance form an interrogation circuit; (iii) feeding signals of different frequencies into the first coil; (iv) measuring an electrical parameter such as current, voltage, or impedance on the first coil; (v) determining a resonance frequency of the interrogation circuit; and (vi) assigning the resonance frequency to at least one added further impedance, and thus to a switch element connecting this impedance.

### BRIEF DESCRIPTION OF THE DRAWINGS

The invention is described below by way of examples, without any limitation of the general inventive concept, on embodiments and with reference to the drawings.

FIG. 1 schematically shows in general form a device for non-contacting interrogation of system states;

FIG. 2 shows a variant of the invention with a plurality of switch elements and a plurality of further impedances in form of capacitances;

FIG. 3 shows a further embodiment of the invention with impedances in form of inductances connected in series;

FIG. 4 shows a further embodiment of the invention with a tunable capacitance; and

FIG. 5 shows another embodiment with a resonance circuit as an impedance.

### DETAILED DESCRIPTION OF PREFERRED EMBODIMENTS

FIG. 1 schematically shows a device in accordance with the invention in general form. The fixed part 10 is associated with a first coil 11 fed by a signal generator 12, and also an evaluation unit 13. The rotatable part 20 which is rotatable relative to the fixed part 10 is associated with a second coil 21 with at least one capacitance 22, and also a switch element 23 which can connect an impedance 24 onto the resonance circuit. The two coils 11 and 12 are magnetically coupled to each other. In the example shown here this results merely from the close spatial arrangement. In order to improve the coupling it is possible optionally to use ferrite or iron materials in addition to coils made of a plurality of windings. When the switch element 23 is open, the additional impedance 24 is decoupled from the resonance circuit. The resonance frequency is therefore determined by the second coil 21 and also the capacitance 22. When the switch element 23 is closed, the impedance 24 is connected parallel to the second coil 21 and the capacitance 22. If this impedance 24 is a capacitance, for example, then the resonance frequency decreases owing to and in accordance with the higher total capacitance of the parallel resonance circuit.

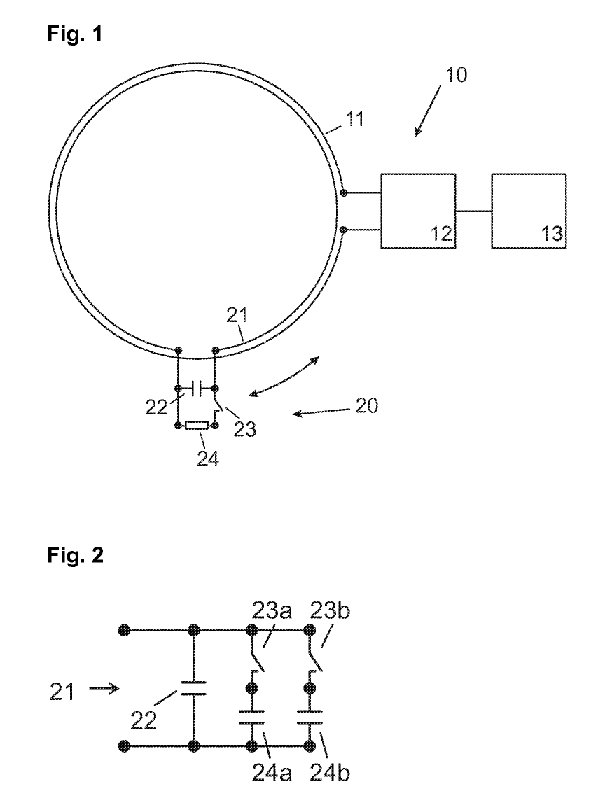

FIG. 2 shows a variant of the invention with a plurality of switch elements and a plurality of further impedances in form of capacitances. Here too, a capacitance 22 is connected in parallel with the second coil 21 which is not shown here for reasons of clarity of illustration. Furthermore, a first series connection of a first switch element 23a and a first impedance 24a in the form of a capacitance, and also a second switch element 23b and a second impedance 24b also in the form of a capacitance, are connected in parallel with this. When both switch elements are open, the resonance frequency of the resonance circuit is determined by the inductance 21 and the capacitance 22. By closing at least one switch element, the resonance frequency can be reduced by the connection of the respective capacitance into the circuit. The resonance frequency can be reduced further by connecting the second capacitance into the circuit. With suitable dimensioning of the capacitances, characteristic resonance frequencies are obtained for each combination of the switch positions. Thus in an advantageous manner the capacitance 24a is twice as large as the capacitance 22, and the capacitance 24b is four times as large as the capacitance 22. If inductances were used in this example instead of the capacitances, the inductance of the resonance circuit would be decreased by parallel connection in the case of closed switch elements, and the resonance frequency would be increased accordingly. It is also possible to combine inductances and capacitances with each other. Thus, for example, instead of the shown capacitance 24a an inductance could be connected into the circuit in series with the switch element 23a. With this, for a closed switch element 23a the resonance frequency would become higher than the resonance frequency with open switch elements. When the switch element 23b in series with the capacitance 24b is closed, the resonance frequency would decrease.

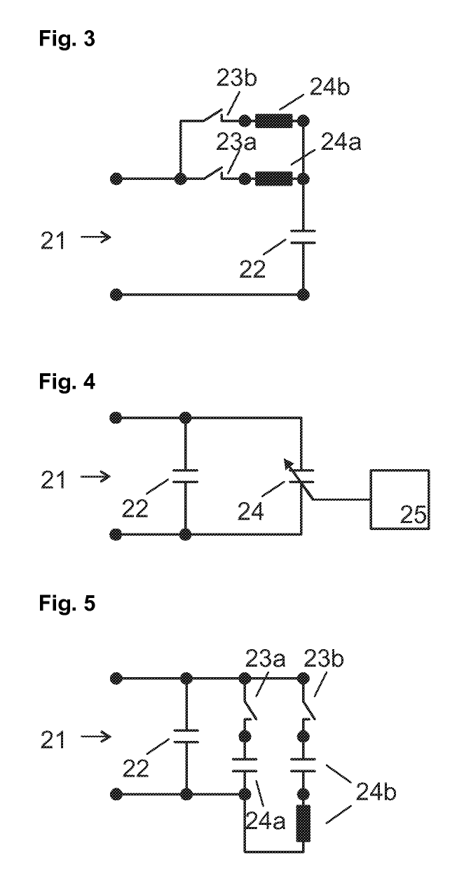

FIG. 3 shows a further embodiment of the invention with impedances in the form of inductances connected in series. Different resonance frequencies can be generated by connecting the inductances 24a or 24b into the circuit in series with the second coil 21. In the present case, the resonance circuit is interrupted when all switch elements are open. This can be remedied, for example, by connecting an inductance (not shown here in closer detail) into the circuit in parallel with the switch elements including the inductances. The inductances 24a and 24b could also be connected fixedly in series between the second coil 21 and the capacitance 22, with the inductance 24a then being bridged by a switch element 23a connected in parallel with the same, and the inductance 24b by a switch element 24b connected in parallel with the same. Furthermore, here too inductances and capacitances can be combined with each other. Similarly, instead of an inductance as an impedance, a resonance-capable structure such as a resonance circuit can be inserted into the circuit. This can have an optional attenuation in the form of a resistance.

FIG. 4 shows a further embodiment of the invention with a tunable capacitance. Such a tunable capacitance can be, for example, a variable capacitance diode, a capacitor value set as a result of a mechanical system state (e.g. the plate separation of a plate capacitor), or also a variable disk capacitor moved by a motor. This tunable capacitance is controlled by a control unit 25. Control may be effected, for example, in accordance with the measurement signal of a sensor. Corresponding to a tunable capacitance, it is also possible to embody a tunable inductance, or also a variable resistance. In this case, for example, it is possible to change the magnetic constant of a ferrite or iron core with a superimposed static field, or by mechanical movement of a core. A potentiometer could also be used. Similarly, it is also possible to use dissipative magnet cores by means of which the losses of an inductance are changed with variation of core position, for example.

FIG. 5 shows another embodiment of the invention with a resonance circuit as an impedance. The arrangement substantially corresponds to the arrangement of FIG. 2. Here, however, a resonance circuit consisting of a series connection of an inductance and a capacitance is provided for the impedance 24b instead of the capacitance. Here too, the resonance frequency of the arrangement can also be determined as described above. From this it is again possible to draw conclusions about the capacitance or inductance.

A device in accordance with the invention for non-conducting interrogation of system states of a rotatable part 20 that is rotatable relative to a fixed part 10 is based on inductive coupling. The fixed part 10 comprises a first coil 11 which is fed from a signal generator 12. A second coil 21 arranged on the rotatable part 20 is magnetically coupled with the first coil 11. The coils can be embodied optionally as simple conductor loops, coils with bifilar windings forming a locally bounded field resulting from anti-parallel currents, air-core coils, or also coils with iron or ferrite cores. Similarly, combinations of various types of coils are possible. With this, a magnetic coupling of the first coil 11 with the second coil 21 is essential. The second coil 21 is supplemented with at least one capacitance 22 to form a resonance circuit. This at least one capacitance 22 can be designed as a discrete component. Similarly, however, it can also be a parasitic capacitance of the arrangement. Furthermore, at least one switch element 23a, 23b is provided which connects at least one further impedance 24a, 24b to the resonance circuit. Here the circuit can be optionally a series circuit or even a parallel circuit. A switch element can be, for example, a semiconductor switch or also a mechanical switch. Here the term impedance relates to an electronic component which has a real and/or imaginary impedance. This can be an inductance, a capacitance, or a resistance. Combinations are also possible, such as a resonance circuit consisting of an inductance and a capacitance. More complex resonance circuits made up of series connections and parallel connections having a plurality of resonances are also possible. For this it is of importance that at least one electrical property of the resonance circuit is changed by the addition of the at least one further impedance. It is especially advantageous when the at least one electrical property of the resonance circuit is changed substantially, preferably by a factor of two, more preferably by a factor of ten, so that a distinctly measurable effect is caused.

In accordance with the invention, the frequency of a signal generator 12 which is assigned to the fixed part 10 is changed until at least one resonance frequency of the arrangement is reached. Here this may be a series resonance or a parallel resonance. The control of the signal generator is effected by means of an evaluation unit 13 which further comprises means for determining a resonance frequency. These can be means, for example, for measuring the current amplitude, the voltage amplitude, the time progression of the current, its time progression of voltage or also impedance. For determining a resonance frequency, it is also possible optionally to determine a current, a voltage, and/or an impedance of the resonance circuit in addition to the frequency. It is possible to draw conclusions about the electric switch element 23a, 23b activated at any time from the frequency or another electrical variable. If in the case of a parallel resonance circuit, for example, a further resonance capacitance is connected in parallel with the at least one capacitance 22 with a switch element, then the resonance frequency of the parallel resonance circuit will decrease accordingly. The value of the capacitance can now be determined from the new resonance frequency, and it is now possible to draw conclusions about the thus activated switch element. Similarly it would be possible, for example, for a table to be provided in the evaluation unit, which contains a direct relationship between a resonance frequency and the switch element activated for this. A corresponding evaluation must also be performed in the case of a parallel connection of an inductance, or also in the case of a further series connection of an inductance or a capacitance with the at least one capacitance 22. The same also applies to an arrangement with a series resonance circuit. If now, for example, a resistance is inserted in parallel or in series with the resonance circuit instead of an inductance or a capacitance, then there is a change of the attenuation of the resonance circuit at the resonance frequency, which can be determined by a measurement of at least one electric voltage or an electric current or an impedance by an evaluation unit 13. From this it is also possible to draw conclusions about the switch element, as previously described.

Instead of the above described controllable signal generator 12, a further device in accordance with the invention comprises a freely oscillating signal generator, the frequency of which is determined by the resonance circuit. If now a further, preferably imaginary impedance is inserted in the resonance circuit by at least one switch element, then the resonance frequency of the resonance circuit, and with it also the operating frequency of the signal generator changes accordingly. An evaluation can be performed by the evaluation unit 13, as described above.

In another device in accordance with the invention, a signal generator 12 is provided, the operating frequency of which can be changed within a predetermined frequency range under the control of the evaluation unit. The evaluation unit further comprises means for measuring at least one electrical parameter such as frequency, amplitude, phase on the first coil. This measurement can be made directly on the first coil, but also indirectly, for example in a decoupled manner by means of further electronic components. As a result of the evaluation of the measured results, as was already described above, it is also possible to draw conclusions about the respectively activated switch element. It is possible, for example, to determine an attenuation or also an impedance, preferably according to magnitude and phase, at a certain frequency, preferably at a plurality of frequencies. It is thus especially advantageous to draw conclusions from the magnitude and phase of the impedance about the corresponding impedances, or the inductances, capacitances, or resistances connected to the resonance circuit, and thus about the activated switch elements.

A further device in accordance with the invention comprises a signal generator 12 which is controlled by an evaluation unit 13 in such a way that it emits signals of a plurality of frequencies. Furthermore, the evaluation unit 13 is designed in such a way that it can recognize at least one, preferably a plurality of different resonance frequencies as a result of the measurement of at least one electrical parameter such as frequency, amplitude, phase on the first coil, and can draw conclusions therefrom about the activated switch elements. The signals emitted by the signal generator 12 can be, for example, pulses, preferably short pulses, broadband noise, or also multi-frequency signals having frequency components at the possible resonance frequencies of the arrangement. Evaluation is now effected preferably in a frequency-selective manner, for example by filtering with discrete filters or also a Fourier transformation. As a result of such design it is possible to recognize different switch states within a short time or simultaneously.

At least one means for plausibility checks is provided in an especially advantageous embodiment of the invention. This can be, for example, a component of the evaluation unit 13. For performing plausibility checks, the results of performed measurements are compared with predetermined setpoint values. When, for example, a total of four resonance frequencies of the arrangement are possible in the case of two switch elements, then they can be compared with predetermined setpoint frequencies. If the actually determined resonance frequencies lie within a permissible tolerance field around the setpoint frequencies, a valid measurement signal can be signaled. However, when they lie outside a permissible tolerance field, an error of the measurement can be signaled. With this embodiment it is possible, for example, to recognize and signal interruptions or short circuits in the line system, increased mechanical tolerances between the mutually movable parts, or other faults, or an ageing of the components. Similarly, an error can be signaled when resonance is no longer possible or lies outside a predetermined frequency range.

As already described above, individual system states can be queried in a non-contacting manner. Similarly, the device in accordance with the invention can be used to transmit any digital information in a non-contacting manner. Transmission can be effected, for example, by time-controlled activation or deactivation of one switch element or a plurality switch elements simultaneously. When a plurality of switch elements are activated simultaneously, then a plurality of bits of information can be transmitted simultaneously.

In another embodiment of a device in accordance with the invention, it is additionally possible to couple out auxiliary power from the second coil 21 for feeding electronic components on the side of the rotatable part 20. However, an actual encoding and transmission of information according to the invention is effected without any such additional coupling-out of auxiliary power.

An increased precision of the evaluation can be achieved by reference measurement. It is thus possible, for example, for a first impedance to be measured with a reference channel comprising a further first coil 11 fed by a further first signal generator 12 and also a further second coil 21 coupled therewith, and to be connected to the actual measuring channel with a changeover switch.

A further embodiment of a device in accordance with the invention consists in the first coil 11 and/or the second coil 21 optionally comprising a plurality of coil sections. These coil sections also can be coupled magnetically with each other. Thus, for example, a first coil section of the first coil 11 can be fed by the signal generator 12, whilst a second coil section of the first coil 11 is used by the evaluation unit 13. Similarly, different impedances can be connected by means of switch elements to different coil sections of the second coil 21. The various coil sections need not be connected with each other in a mechanically rigid way but can be movable relative to each other. In this way it is possible to query system states of different parts that move at different speeds or are located at different positions.

A method in accordance with the invention for non-contacting querying of system states of a part 20 that is rotatable relative to a fixed part 10, with the fixed part 10 having a first coil 11 fed by a signal generator 12 and the rotatable part 20 having a second coil 21 that is magnetically coupled with the first coil 11, comprises the following steps: (i) supplementing the second coil 21 with at least one capacitance to form a resonance circuit; (ii) connecting into the circuit at least one further impedance using at least one further switch element; (iii) feeding signals of different frequencies into the first coil 11; (iv) measuring an electrical parameter such as current, voltage, or impedance at the first coil 11; (v) determining a resonance frequency of the arrangement; and (vi) assigning the resonance frequency to at least one further impedance and thus to the switch element connecting this impedance into the circuit.

For reasons of simplified illustration, reference is here made to the transmission between a fixed and a rotating part. However, the question of which part rotates relative to the other part is principally a question of the local reference. It would also be possible for both parts to rotate relative to a fixed position on earth; it being essential for the invention that both parts are rotatable relative to each other. Similarly, the invention can also be applied to units moving linearly relative to each other.

1. A device for non-contacting interrogation of system states of a part that is rotatable relative to a fixed part, comprising:
a first coil on the fixed part;
a signal generator for feeding the first coil;
a second coil on the rotatable part, which is magnetically coupled with the first coil, wherein the second coil is supplemented with at least one capacitance to form a resonance circuit;
at least one switch element for connecting or disconnecting at least one further impedance into or from the resonance circuit is provided, whereby the first coil, the second coil, the at least one capacitance, the at least one switch element, and also the at least one further impedance form an interrogation circuit; and
an evaluation unit is provided on the fixed part for changing a frequency of the signal generator until at least one resonance frequency of the interrogation circuit is attained, and for drawing conclusions about a state of the at least one switch element from at least one of an attained resonance frequency and an attenuation of the interrogation circuit.

2. The device according to claim 1, wherein means for plausibility check by comparing determined electrical parameters with predetermined values are provided in order to indicate faults of the arrangement in case of large deviations.

3. The device according to claim 1, wherein the at least one further impedance is dimensioned so that distinct resonance frequencies occur for all states of the switch elements.

4. The device according to claim 1, wherein optionally at least one of the first coil and the second coil comprises a plurality of coil sections.

5. A device for non-contacting interrogation of system states of a part that is rotatable relative to a fixed part, comprising:
a first coil on the fixed part;
a signal generator for feeding the first coil;
a second coil on the rotatable part, which is magnetically coupled with the first coil, wherein the second coil is supplemented with at least one capacitance to form a resonance circuit;
at least one switch element for connecting or disconnecting at least one further impedance into or from the resonance circuit is provided, whereby the first coil, the second coil, the at least one capacitance, the at least one switch element, and also the at least one further impedance form an interrogation circuit; and
the signal generator is adapted to be freely oscillating based on the resonance circuit, and an evaluation unit is provided on the fixed part for evaluating a frequency of the signal generator and drawing conclusions about a state of the at least one switch element from at least one of a resonance frequency and an attenuation of the interrogation circuit.

6. The device according to claim 5, wherein means for plausibility check by comparing determined electrical parameters with predetermined values are provided in order to indicate faults of the arrangement in case of large deviations.

7. The device according to claim 5, wherein the at least one further impedance is dimensioned so that distinct resonance frequencies occur for all states of the switch elements.

8. The device according to claim 5, wherein optionally at least one of the first coil and the second coil comprises a plurality of coil sections.

9. A device for non-contacting interrogation of system states of a part that is rotatable relative to a fixed part, comprising:
a first coil on the fixed part;
a signal generator for feeding the first coil;
a second coil on the rotatable part, which is magnetically coupled with the first coil, wherein the second coil is supplemented with at least one capacitance to form a resonance circuit;
at least one switch element for connecting or disconnecting at least one further impedance into or from the resonance circuit is provided, whereby the first coil, the second coil, the at least one capacitance, the at least one switch element, and also the at least one further impedance form an interrogation circuit; and
an evaluation unit is provided on the fixed part for changing a frequency of the signal generator within a predetermined frequency range and simultaneously performing measurements of at least one electrical parameter selected from frequency, amplitude, and phase on the first coil, and based on this draws conclusions about a state of the at least one switch element.

10. The device according to claim 9, wherein means for plausibility check by comparing determined electrical parameters with predetermined values are provided in order to indicate faults of the arrangement in case of large deviations.

11. The device according to claim 9, wherein the at least one further impedance is dimensioned so that distinct resonance frequencies occur for all states of the switch elements.

12. The device according to claim 9, wherein optionally at least one of the first coil and the second coil comprises a plurality of coil sections.

13. A device for non-contacting interrogation of system states of a part that is rotatable relative to a fixed part, comprising:
a first coil on the fixed part;
a signal generator for feeding the first coil;
a second coil on the rotatable part, which is magnetically coupled with the first coil, wherein the second coil is supplemented with at least one capacitance to form a resonance circuit;
at least one switch element for connecting and disconnecting at least one further impedance into or from the resonance circuit is provided, whereby the first coil, the second coil, the at least one capacitance, the at least one switch element, and also the at least one further impedance form an interrogation circuit; and
an evaluation unit is provided on the fixed part for controlling the signal generator so that it emits a signal having a plurality of frequencies and simultaneously performs measurements of at least one electrical parameter selected from frequency, amplitude, and phase on the first coil, and based on this draws conclusions about a state of the at least one switch element.

14. The device according to claim 13, wherein means for plausibility check by comparing determined electrical parameters with predetermined values are provided in order to indicate faults of the arrangement in case of large deviations.

15. The device according to claim 13, wherein the at least one further impedance is dimensioned so that distinct resonance frequencies occur for all states of the switch elements.

16. The device according to claim 13, wherein optionally at least one of the first coil and the second coil comprises a plurality of coil sections.

17. A method for non-contacting interrogation of system states of a part that is rotatable relative to a fixed part, with the fixed part having a first coil fed by a signal generator, and the rotatable part having a second coil which is magnetically coupled with the first coil, comprising the following steps:
supplementing the second coil with at least one capacitance to form a resonance circuit;
adding at least one further impedance using at least one switch element, whereby the first coil, the second coil, the at least one capacitance, the at least one switch element, and also the at least one further impedance form an interrogation circuit;
feeding signals of different frequencies into the first coil;
measuring an electrical parameter such as current, voltage, or impedance on the first coil;
determining a resonance frequency of the interrogation circuit; and
assigning the resonance frequency to at least one added further impedance, and thus to a switch element connecting this impedance.
